(19) United States
(12) Patent Application Publication
(10) Pub. No.: US 2011/0227621 A1
(43) Pub. Date: Sep. 22, 2011

(54) GAIN NORMALIZATION OF A TIME-TO-DIGITAL CONVERTER

(75) Inventor: Timothy John Ridgers, Bayeux (FR)

(73) Assignee: NXP B.V., Eindhoven (NL)

(21) Appl. No.: 13/129,564

(22) PCT Filed: Nov. 16, 2009
(86) PCT No.: PCT/IB09/55079

§ 371 Date: May 16, 2011

(30) Foreign Application Priority Data
Nov. 17, 2008 (EP) 08291069.6

(51) Int. Cl. H03L 7/06; H03M 1/50

(52) U.S. Cl. 327/159; 341/168

(57) ABSTRACT

The invention relates to normalisation of a TDC system (20). The TDC system (20) comprises a TDC core (21), a gain normalization circuit (22) and an adjuster (23). The TDC core (21) comprises a set of nominally identical delay elements and converts the time difference between the edges of a reference clock signal (FREF) and a controllable clock signal (CLK) into a raw TDC output code as a digital word. The adjuster (23) is configured to carry out the gain normalisation by adjusting the output code. The gain normalization circuit (22) comprises at least a processor for analyzing the occurrence probability of the output code values, and for determining the adjustment to be made by the adjuster (23) according to said occurrence probability.

### FIELD OF THE INVENTION

The invention relates to the field of communications, and more particularly to the gain normalization of a time-to-digital converter (TDC).

### BACKGROUND OF THE INVENTION

Frequency synthesizers using analog circuit techniques are well known in the art. A frequency synthesizer is a key block inside a radio frequency (RF) transceiver, which is used for both up-conversion and down-conversion of radio signals.

However, advanced deep sub-micron CMOS technology, such as 90, 65 or 45 nm, is not very compatible with such analog frequency synthesizers in terms of integration and is also difficult to render compliant to multi-mode radio standards, such as combining GSM, EDGE, UMTS, CDMA, Bluetooth, WLAN and DECT. Thus, the current design trend is towards replacing such analog frequency synthesizer architectures based on the voltage-controlled oscillator (VCO) and a combination of phase/frequency detector and charge-pump, by an all-digital phase-locked loop (ADPLL) frequency synthesizer architecture based on a digitally controlled oscillator (DCO) and a time-to-digital converter (TDC), respectively.

In order to fully obtain the expected performance, a correct TDC gain normalization to the oscillator period is required to allow the TDC to provide a fine timing resolution.

FIG. 1 shows a block diagram of a conventionally normalized TDC 100. It comprises a TDC 110, a gain normalization circuit 120 and a multiplier block 130. The TDC 110 is aimed at providing an output code as a digital encoded phase information below 2π, which is finer than the period of the DCO clock signal CLK. The TDC 110 comprises a set of nominally identical delay elements and converts the time difference between the edges of a reference clock signal FREF, derived for example from a crystal oscillator, and the DCO clock signal CLK into a TDC output code as a digital word. The former clock signal FREF initiates the measurement, while the latter CLK terminates the measurement until the next reference clock cycle. For example, if we consider that all the delay elements have an identical nominal value of 25 ps, then the TDC 110 is capable of resolving the accumulated oscillator phase to a tenth of its period when running at 4 GHz, namely to within 0.2π radian. The increased resolution produces a lower quantization noise with respect to the phase measurement, thereby resulting in a lower phase noise introduced by the ADPLL-based RF frequency synthesizer. In order to combine together the output code issued from the TDC 110 and the accumulated number of complete DCO clock cycles in a phase-consistent form, the TDC gain is then normalized to the period of the DCO at its specific operating frequency. Thereby, the multiplier block 130 adjusts the TDC output code by multiplying it with a proportionality constant estimated by the gain normalization circuit 120.

However, process, voltage, temperature (PVT) variations may lead to an incorrect TDC gain assessment. For example, the nominal value of the delay elements may drop 20%, which is quite comparable, for example, to the CMOS speed increase at low temperatures or to the random manufacturing variation. Numerically, that means that if all the delay elements have a nominal value of 25 ps, then their value will decrease until 20 ps. Thus, a TDC output code “10” would correspond to a delay of 200 ps instead of the 250 ps normally expected, thereby contributing to TDC transfer curve errors. In particular, the resulting 50 ps error in estimating the oscillator phase would be two times the quantization step, thereby introducing a noise term that would seriously degrade the in-lock PLL noise performance.

Moreover, poor TDC gain normalization or random manufacturing tolerances may also lead to an incorrect TDC gain assessment when frequency-modulation is implemented. Indeed, errors in the step size assigned between the TDC output codes can create non-linearity, which affects the modulation spectrum and is susceptible to create unwanted spectral growth and thereby non-compliance to system radio specifications.

### SUMMARY OF THE INVENTION

It is therefore an aim of the invention to provide an improved gain normalization of a time-to-digital converter.

In accordance with a first aspect of the invention, there is provided a time-to-digital converter (TDC) system for use in an all-digital phase-locked loop circuit, said TDC system comprising:
a TDC core configured to receive a controllable clock signal from a controllable oscillator and a reference clock signal from a reference oscillator, and to convert a time difference between the edges of said controllable clock signal and said reference clock signal into an output code; and
a gain correction circuit for correcting the gain of said TDC core, said gain correction circuit comprising:
a gain normalization circuit configured to normalize the gain of said TDC core to the period of said controllable oscillator; and
an adjuster in connection with said gain normalization circuit, said adjuster configured to carry out the gain normalisation by adjusting said output code; wherein,
said TDC core comprises a set of nominally identical delay elements, each delay element introducing a unit delay; and
said gain normalization circuit comprises a processor configured to analyze the occurrence probability of said output codes, and to determine the adjustment to be made by the adjuster according to said occurrence probability.

Thereby, the gain assessment of the TDC core is based on the analysis of the occurrence probability of the output codes.

The adjuster may be a multiplier, the multiplier being configured to multiply the output code by a correction coefficient. Thereby, a code-to-phase adjustment associated for each output code can be achieved.

The adjuster may be a look-up table, the look-up table being configured to assign a corresponding phase error estimate to each output code. Thereby, the code-to-phase adjustment associated for each output code can be made finer and the results of the occurrence probabilities can also be used to correct for TDC non-linearities.

The clock signal may be provided to the TDC core through a delay element. Thereby, effects due to dead-zones can be removed.

The processor may estimate the number N of the unit delays per oscillator cycle according to the relation:

$$\begin{matrix}N = \{ ( code {value}_{last but one} ) + \frac{{occurrence}_{last code}}{{averageoccurrences}_{all other codes}} \} \\ = \frac{oscillator period}{unit delay} ,\end{matrix}$$

where code value_{last but one} is the value of the last but one output code, and oscillator period is the period of the oscillator, when there is not the delay element. Thereby, it is possible to obtain a precise evaluation of the number N of unit delays per oscillator cycles, and hence, the mean unit delay estimate.

The processor may estimates the number N′ of the unit delays per oscillator cycle according to the relation:

$$\begin{matrix}{N}^{′} = \{ \begin{matrix}( {codevalue}_{last but one} - {codevalue}_{second} ) + \\ \frac{{occurrence}_{last code} + {occurrence}_{first code}}{{averageoccurrences}_{all other codes}}\end{matrix} \} \\ = \frac{oscillator period}{unit delay} ,\end{matrix}$$

where code value_{last but one} is the value of the last but one output code, code value_{second} is the value of the second output code, and oscillator period is the period of said oscillator (50), when there is the delay element. Thereby, it is possible by calculating N′ to improve the previous evaluation of the number N of unit delays per oscillator cycles, and hence, the mean unit delay estimate.

In accordance with a second aspect of the invention, there is provided a method of normalizing the TDC system of the first aspect, the method comprising:
determining the occurrence probability by counting the number of occurrences for each code value and comparing to the total number of code values; and
adjusting the adjuster according to said occurrence probability to normalize the gain of said TDC core to the period of said controllable oscillator.

The steps of the method can be carried out by a computer program comprising program code means when the computer program is carried out on a computer.

Further aspects of the invention provide an all-digital phase-locked loop (ADPLL) circuit comprising the previous TDC system, and a system-on-chip (SOC) circuit comprising the previous ADPLL circuit.

Still further aspects provide a computer readable storage medium storing a test program controlling the TDC system for allowing determination of acceptance and rejection of the previous TDC system according to a predetermined number of occurrences of each value of the output codes.

Yet a further aspect provides an integrated circuit comprising the TDC system, wherein the gain correction circuit is implemented off-chip, i.e. outside the integrated circuit, and the results, i.e. the correction coefficient or the content of the look-up table, provided by the gain correction circuit are stored within the integrated circuit. For example, in certain embodiments the TDC gain normalisation calculation may only be performed off-chip, e.g. in a production test environment, and then the circuit can be programmed with the appropriate adjustment coefficient or table of values in a storage element, such as a one-time programmable (OTP) memory, for storing these results.

An integrated circuit may comprise a plurality of the TDC systems, wherein each TDC system is configured to share the same gain correction circuit, provided that the gain normalizations of the TDC cores are performed at different moments for each TDC system.

### BRIEF DESCRIPTION OF THE DRAWINGS

These and other aspects and advantages of the invention will be apparent from and elucidated with reference to the non-limiting embodiments described hereinafter. In the drawings:

FIG. 1 shows a block diagram of a conventionally normalized time-to-digital converter (TDC);

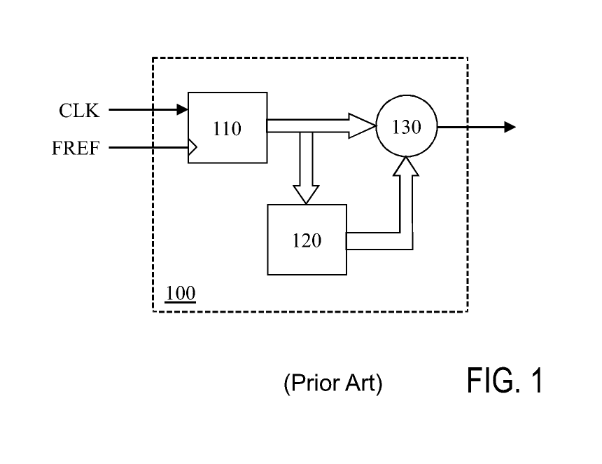

FIG. 2 shows a block diagram of a system-on-chip (SOC) having an all-digital phase-locked loop (ADPLL) according to an embodiment of the invention;

FIG. 2a shows a block diagram of the oscillator cycle accumulator of FIG. 2;

FIG. 2b shows a block diagram of the TDC system of FIG. 2;

FIG. 3 shows a diagram illustrating a TDC transfer function of a code value issued from the TDC core (vertical axis) versus the time difference between the edges of an oscillator clock signal and a reference clock signal (horizontal axis) provided to the input of the TDC core;

FIG. 4 shows a diagram illustrating the number of occurrences for each code (vertical axis) versus the code value (horizontal axis);

FIG. 5 shows a diagram illustrating a TDC transfer function of a code value issued from the TDC core (vertical axis) versus the time difference between the edges of an oscillator clock signal and a reference clock signal (horizontal axis) provided to the input of the TDC core, in the case that an additional delay is introduced at the input of the TDC core in the oscillator path; and

FIG. 6 shows a diagram illustrating the number of occurrences for each code (vertical axis) versus the code value (horizontal axis), in the case that an additional delay is introduced at the input of the TDC core in the oscillator path.

### DETAILED DESCRIPTION OF EMBODIMENTS

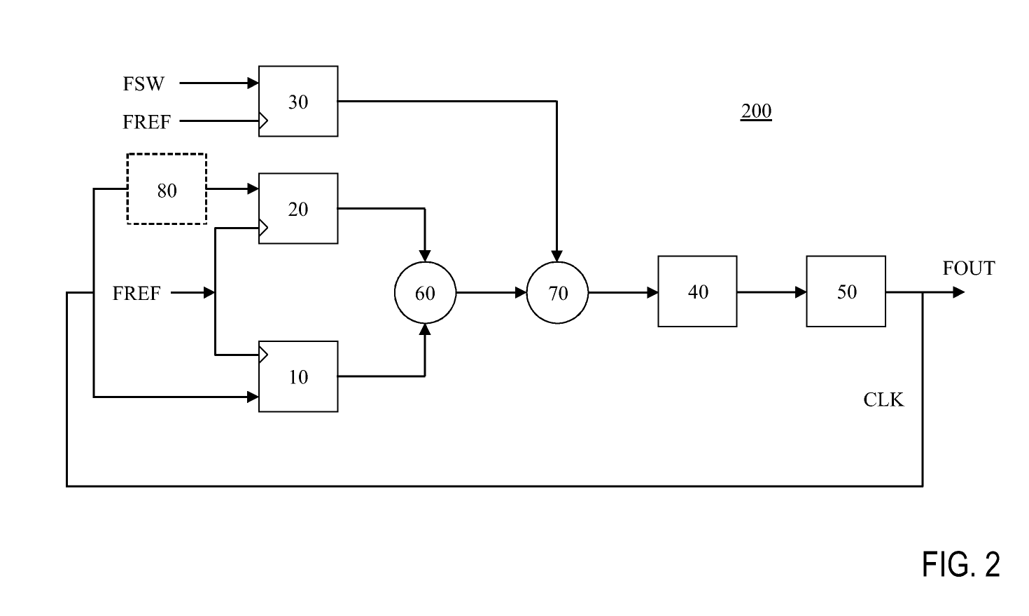

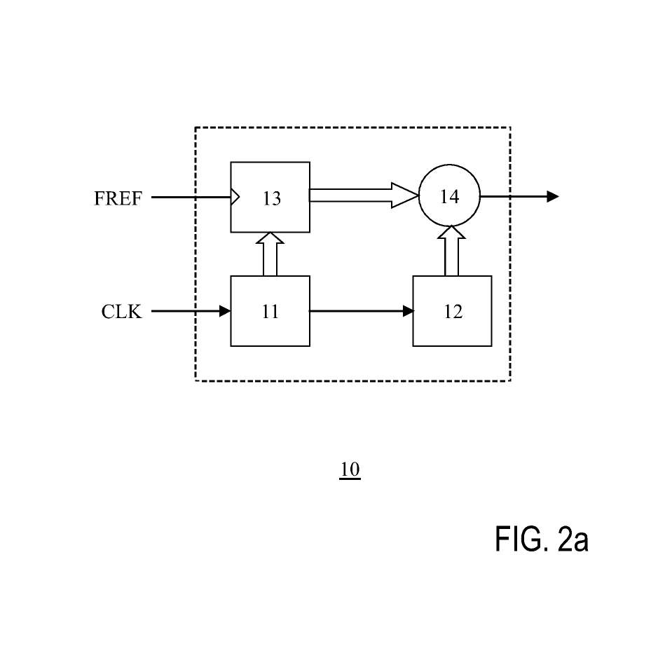

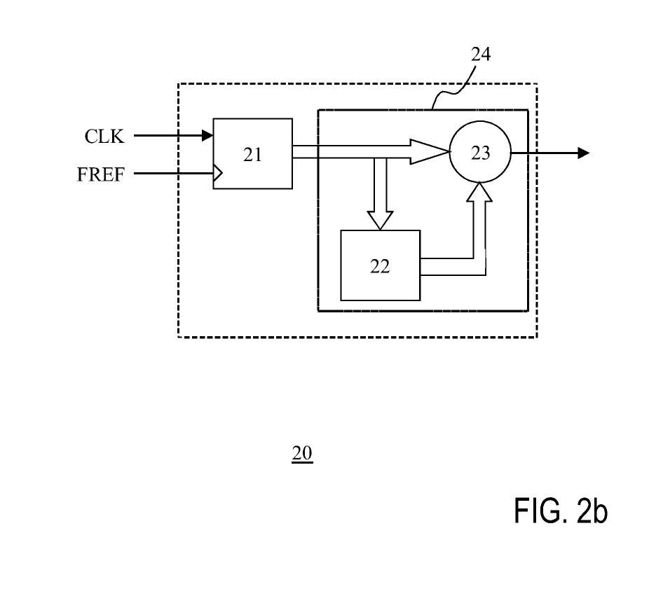

FIG. 2 shows a block diagram of a system-on-chip (SOC) having an all-digital phase-locked loop (ADPLL) 200 according to an embodiment of the invention. The ADPLL 200 comprises at least an oscillator cycle accumulator 10, a time-to-digital converter (TDC) system 20, a phase accumulator 30, a loop filter 40, a digitally controlled oscillator (DCO) 50, a summer block 60, and a phase error detector (PED) 70.

Referring to FIG. 2a, the oscillator cycle accumulator 10 comprises a divider 11, which is driven at its input by the clock signal CLK from the DCO 50 and whose internal state is changed at each active input clock edge, a counter 12, a state decoder 13 and a summer block 14. When the divider 11 exceeds the maximum count of state changes, which is determined by the number of divider stages, an overflow clock signal is generated to drive the counter 12. The state of the divider 11 is read by the state decoder 13 once per reference clock cycle, for example on the clock rising edge. The reference clock signal FREF at the input of the state decoder 13 is derived for example from a crystal oscillator (not shown), which may be generated on-chip and also be digitally controlled, and determines the rate at which the ADPLL 200 calculates and subsequently adjusts the DCO frequency to a predetermined value. Such a state decoder 13 can be built with an appropriate structure using logic gates and bistables. Each of the counter 12 and the state decoder 13 provides a signal as a digital word to the summer block 14, which gives a resultant digital word indicating the accumulated number of complete DCO clock cycles. If the divider 11 acts as a divide-by-N divider and operates with a period between overflow clocks that is a power of two multiple of the input clock edge from the DCO 50, both signals are indeed combined together through the summer block 14 for aligning the bits of their respective digital word, such that the resulting digital word issued from the summer block 14 is in a phase-consistent form that indicates the accumulated oscillator phase to the nearest 2π radians. For example, if we consider that the DCO 50 operates at a frequency of 4 GHz, a typical local oscillator (LO) frequency used in a global system for mobile communications (GSM) transceiver, then the precision obtained in time can be to within 250 ps.

Referring to FIG. 2b, the TDC system 20 according to an embodiment of the invention comprises a TDC core 21 and a gain correction circuit 24, which comprises a gain normalization circuit 22 and an adjuster 23. The TDC core 21 is aimed at providing a raw output code as a binary encoded phase information below 2π, which is finer than the period of the DCO clock signal CLK. The TDC core 21 comprises a set of nominally identical delay elements and converts the time difference between the edges of the reference clock signal FREF and the DCO clock signal CLK into a TDC output code as a digital word. The former clock signal FREF initiates the measurement, while the latter CLK terminates the measurement until the next reference clock cycle. In order to combine together, through the summer block 60, the raw output code issued from the TDC core 21 and the accumulated number of complete DCO clock cycles issued from the summer block 14 in a phase-consistent form, the TDC gain is then normalized to the period of the DCO 50 at its specific operating frequency.

The proposed TDC gain normalization is based on the analysis of the occurrence probability of a significant amount of TDC output code values and the expected flat probability distribution curve. Indeed, in the case that the reference clock signal FREF and the DCO clock signal CLK run at corresponding frequencies that are not harmonically related, i.e. the product of the former signal FREF with any integer is not equal to the product of the latter signal CLK with another integer, then the resulting TDC phase difference between the edges of the reference clock signal FREF and the DCO clock signal CLK will take on an arbitrary and random sequence of values between 0 and 2π for many successive phase comparison cycles. This corresponds to a range of TDC output code values ranging between 0 and a maximum value corresponding to the last code value. That maximum value is determined by the DCO period in connection with the respective TDC unit delay. For further illustration,

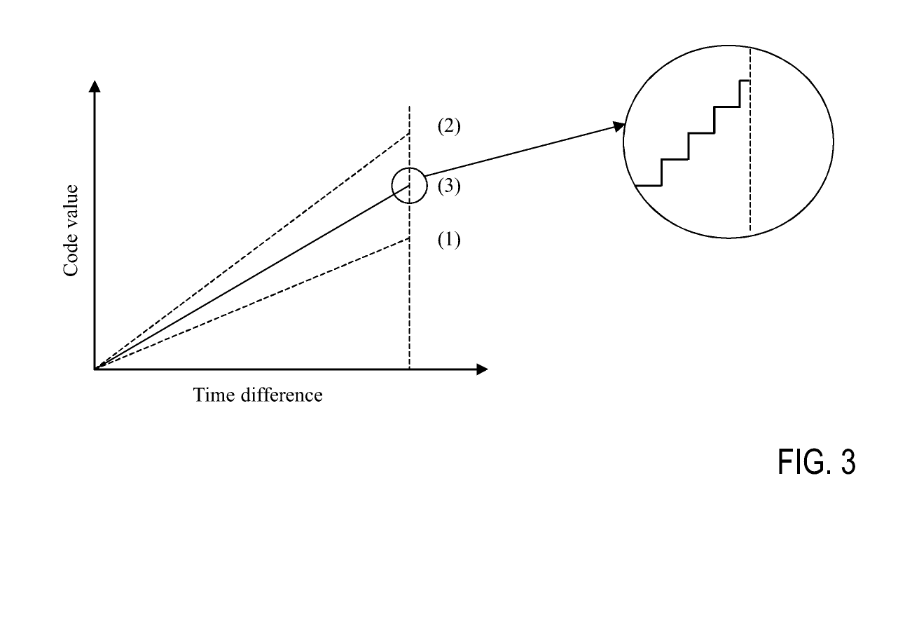

FIG. 3 shows a diagram depicting a TDC transfer function of a digital raw TDC output code value issued from the TDC core 21 on the vertical axis versus the TDC input time difference between the edges of the signals FREF and CLK on the horizontal axis. The diagram shows that the gain slope may vary according to whether the gain is correctly or not assessed. Thus, a nominal, i.e. correct, gain assessment is represented by the solid line (3), a low gain assessment by the dashed line (1), and a high gain assessment by the dashed line (2). The maximum value of the raw TDC output code is related to the DCO period, and the TDC input time difference ranges from 0 to the DCO period value. The occurrence probability of a particular TDC phase difference being equal for all phases, it will result in a flat probability distribution curve.

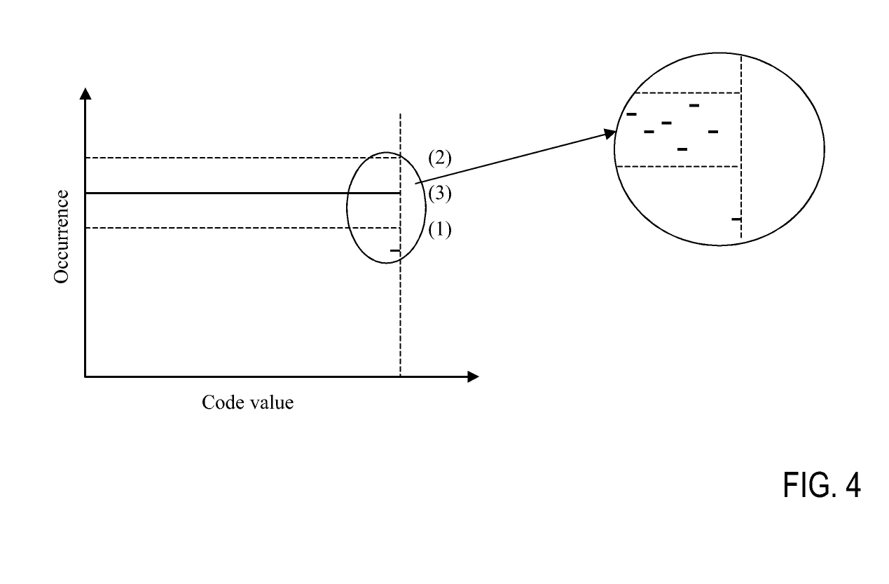

By counting the number of occurrences for each code value and comparing to the total number of samples stored, the TDC gain can be normalized to the DCO period. This is illustrated in the diagram of FIG. 4, wherein the number of occurrences is plotted on the vertical axis versus the code value on the horizontal axis, the dashed lines (1) and (2) corresponding to a respective low and high gain assessment and the solid line (3) to a nominal, i.e. correct, gain assessment. Assumed that each unit delay is equal and sufficient samples are taken to be statistically representative, then the diagram would represent a horizontal line stretching from the code value 0 up to the last but one code value used. In reality, the occurrence probability will vary around the line that represents the average of these code values by an amount due to contributions from statistic uncertainty, and from mismatches between the unit delays inside the TDC core 21 under consideration.

As depicted in FIG. 4, if the particular DCO period does not equal an integral number of TDC unit delays, then it follows that the last code value will occur less frequently since it represents the fractional unit delay that is needed to measure the DCO period. In the particular case (not illustrated) that the DCO period represents an integer number of TDC unit delays, then the occurrence probability of the last code value will be equal to the other code values, i.e. from zero to the last but one code value. Hence, the combination between the value of the last but one code together with the relative proportion of occurrences of the last code value to the average occurrence of all other code values (from zero to the last but one code value), gives a precise estimation of the number N of TDC unit delays per DCO period. This is given by equation (1) as follows:

$$\begin{matrix}N = \{ ( {codevalue}_{last but one} ) + \frac{{occurrence}_{last code}}{{averageoccurrences}_{all other codes}} \} \\ = \frac{DCO period}{TDC unit delay}\end{matrix} \qquad ( 1 )$$

Hence the estimated mean TDC unit delay can be expressed in terms of phase of the DCO signal by the following equation (2):

$$TDC unit delay = \frac{2 π}{\{ ( {codevalue}_{last but one} ) + \frac{{occurrence}_{last code}}{{averageoccurrences}_{all other codes}} \}} \qquad ( 2 )$$

However, in the particular case that the edges of the reference clock signal FREF and the DCO clock signal CLK are quasi-simultaneous, many real TDC circuits exhibit difficulty to properly resolve small phase differences. This may lead to meta-stability, namely to unresolved states due to timing violation when both clock and data bistable inputs change simultaneously. In another particular case, a mismatch in delay between the DCO and TDC paths may create a so-called dead-zone, namely a small time period during which the circuit is not able to recognize the occurrence of the edge of the DCO clock signal CLK.

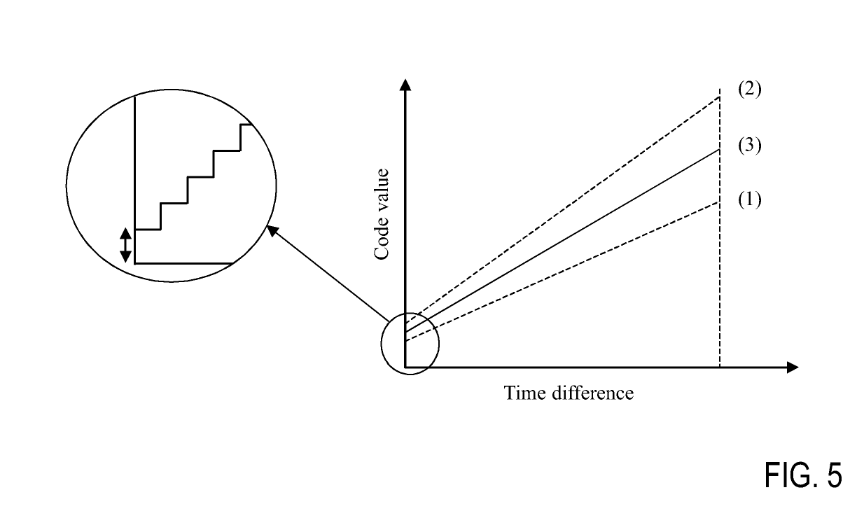

These two cases will create a TDC gain normalization error when considering the previous equations (1) and (2), since the DCO period will not include the time lost in the dead-zone. To avoid this problem, an initial delay introduced by a delay element 80, e.g. a buffer, is added in the DCO path at the input of the TDC core 21 communicating to the DCO 50 (see FIG. 2), but not in the path between the DCO 50 and the divider 11. In this case, the TDC transfer function of FIG. 3 is changed into that of FIG. 5 by the fact that the additional delay introduced by the delay element 80 forces the TDC core 21 to not use the lowest value codes, the dashed lines (1) and (2) corresponding to a respective low and high gain assessment and the solid line (3) to a nominal, i.e. correct, gain assessment. Thereby, both the beginning and the end of a complete DCO period using the TDC unit delay elements can be exactly measured, and the effects due to the dead-zone can be removed. It is to be noted that any constant delay in one path has no effect on the overall ADPLL behaviour.

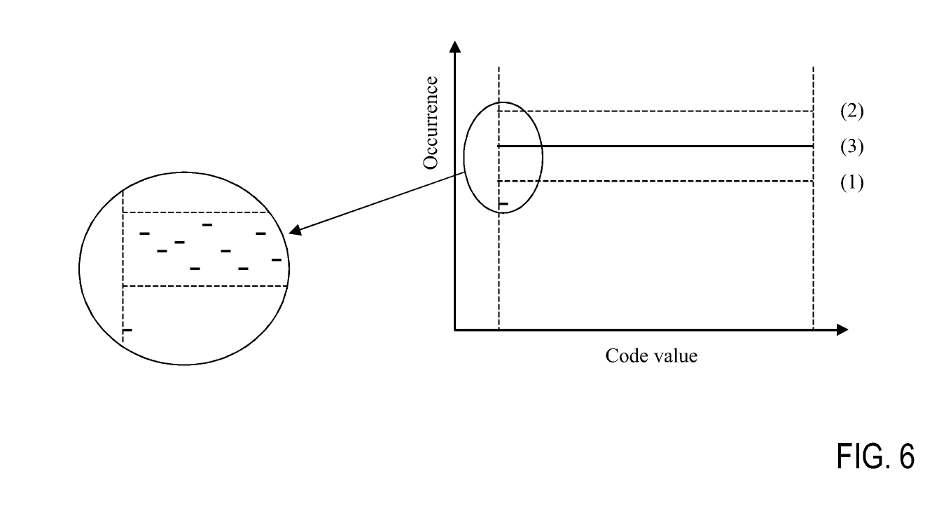

Again, by counting the number of occurrences for each code value and comparing to the total number of samples stored, the TDC gain can be normalized to the DCO period. This is illustrated in the diagram of FIG. 6, wherein the number of occurrences is plotted on the vertical axis versus the code value on the horizontal axis, the dashed lines (1) and (2) corresponding to a respective low and high gain assessment and the solid line (3) to a nominal, i.e. correct, gain assessment. Assumed that each TDC unit delay is equal and sufficient samples are taken to be statistically representative, then the diagram would be truncated with respect to that of FIG. 4 by representing a horizontal line stretching from the first code value (not equal to zero) up to the last but one code value used. In reality, the occurrence probability will vary around the line that represents the average of these code values by an amount due to contributions from statistic uncertainty, and from mismatches between the unit delays inside the TDC core 21 under consideration.

As depicted in FIG. 6, if the particular DCO period does not equal an integral number of TDC unit delays, then it follows that the first and last code values will occur less frequently since they represent the fractional unit delay that is needed to measure the DCO period. In the particular case (not represented) that the DCO period represents an integer number of TDC unit delays, then the sum of the occurrence probabilities of the first and last code values will be equal to that of the other code values (from the second to the last but one code value). Hence, the combination between the value of the second and last but one codes together with the relative proportion of the respective occurrences of the first and last code values to the average occurrence of all other code values, i.e. from the second to the last but one code value, gives a precise estimation of the number N′ of TDC unit delays per DCO period when an additional delay is introduced by the delay element 80. This is given by equation (3) as follows:

$$\begin{matrix}{N}^{′} = \{ \begin{matrix}( {codevalue}_{last but one} - {codevalue}_{second} ) + \\ \frac{{occurrence}_{last code} + {occurrence}_{first code}}{{averageoccurrences}_{all other codes}}\end{matrix} \} \\ = \frac{DCO period}{TDC unit delay}\end{matrix} \qquad ( 3 )$$

Hence, the estimated mean TDC unit delay can be expressed in terms of phase of the DCO signal by the following equation (4):

$$TDC unit delay = \frac{2 π}{\{ \begin{matrix}( {codevalue}_{last but one} - {codevalue}_{second} ) + \\ \frac{{occurrence}_{last code} + {occurrence}_{first code}}{{averageoccurrences}_{all other codes}}\end{matrix} \}} \qquad ( 4 )$$

The detection of the delay element 80 allows the gain normalization circuit 22 to be then adjusted to take into account the offset δ related to the unused lowest code values.

In a first embodiment, the gain normalization circuit 22 comprises at least a storage element, e.g. a first-in first-out (FIFO) buffer memory, for storing the continuously updated sequence of raw TDC output code values provided by the TDC core 21, and a processor for analyzing the content of the storage element.

In a second embodiment, the gain normalization circuit 22 comprises at least a plurality of counters, each of which is associated with a respective TDC output code value, for counting the number of occurrences of each TDC output code value, and a processor for analyzing the content of each counter.

The storage element or the plurality of counters may be implemented within the processor.

The ADPLL-based RF frequency synthesizer first locks the DCO frequency close to its final value by using an initial or previous estimate of the TDC unit delay. Even large errors in this initial estimate will not prevent the ADPLL 200 from achieving lock. Over a significant number of comparison cycles, the accumulated number of complete DCO clock cycles is sufficiently accurate for achieving lock. Once it is estimated that a sufficient number of comparison cycles have been passed with a stable DCO frequency, for example by checking that the frequency control signal delivered by the loop filter 40 does not evolve more than a few least significant bits (LSB) around a mean final value, the content of the storage element in the first embodiment or of the plurality of counters in the second embodiment, is then analyzed through the processor. Alternatively, the TDC output code values generated during the lock process may be used to assess the gain, provided that it is found that the statistical probability of occurrence of each TDC output code value is uniformly distributed during this lock process.

In the case of the first embodiment and based on the equations (1) and (2) when there is not the delay element 80, the analysis performed by the processor consists of bubble-sorting the TDC output code values stored in the storage element, detecting the highest TDC output code value nₘₐₓ, detecting the lowest TDC output code value nₘᵢₙ, counting the number of occurrences of each TDC output code value ranging between nₘᵢₙ and nₘₐₓ, calculating the average occurrence nₘₑₐₙ of all TDC output code values ranging between nₘᵢₙ and nₘₐₓ₋₁, calculating the ratio between the occurrence of nₘₐₓ and the average occurrence nₘₑₐₙ, and making some mathematical operations, such as additions, subtractions and divisions, for finally estimating the mean TDC unit delay in terms of phase of the DCO signal. On the other hand, based on the equations (3) and (4) when there is the delay element 80, the analysis performed by the processor consists of bubble-sorting the TDC output code values stored in the storage element, detecting the highest TDC output code value nₘₐₓ, detecting the lowest TDC output code value nₘᵢₙ, counting the number of occurrences of each TDC output code value ranging between nₘᵢₙ and nₘₐₓ, calculating the average occurrence nₘₑₐₙ of all TDC output code values ranging between nₘᵢₙ₊₁ and nₘₐₓ₋₁, calculating the ratio between the occurrence of nₘᵢₙ and the average occurrence nₘₑₐₙ, calculating the ratio between the occurrence of nₘₐₓ and the average occurrence nₘₑₐₙ, and making some mathematical operations, such as additions, subtractions and divisions, for finally estimating the mean TDC unit delay in terms of phase of the DCO signal.

In the case of the second embodiment and based on the equations (1) and (2) when there is not the delay element 80, the analysis performed by the processor consists of detecting the highest TDC output code value nₘₐₓ, detecting the lowest TDC output code value nₘᵢₙ, retrieving from each counter the number of occurrences of each TDC output code value ranging between nₘᵢₙ and nₘₐₓ, calculating the average occurrence nₘₑₐₙ of all TDC output code values ranging between nₘᵢₙ and nₘₐₓ₋₁, calculating the ratio between the occurrence of nₘₐₓ and the average occurrence nₘₑₐₙ, and making some mathematical operations, such as additions, subtractions and divisions, for finally estimating the mean TDC unit delay in terms of phase of the DCO signal. On the other hand, based on the equations (3) and (4) when there is the delay element 80, the analysis performed by the processor consists of detecting the highest TDC output code value nₘₐₓ, detecting the lowest TDC output code value nₘᵢₙ, retrieving from each counter the number of occurrences of each TDC output code value ranging between nₘᵢₙ and nₘₐₓ, calculating the average occurrence nₘₑₐₙ of all TDC output code values ranging between nₘᵢₙ₊₁ and nₘₐₓ₋₁, calculating the ratio between the occurrence of nₘᵢₙ and the average occurrence nₘₑₐₙ, calculating the ratio between the occurrence of nₘₐₓ and the average occurrence nₘₑₐₙ, and making some mathematical operations, such as additions, subtractions and divisions, for finally estimating the mean TDC unit delay in terms of phase of the DCO signal.

In the case of both embodiments, the gain normalization is then carried out by adjusting through the adjuster 23, e.g. a multiplier, a specific raw TDC output code value by a correction coefficient, e.g. a proportionality constant, determined by the processor.

The respective outputs of the summer block 14 and the adjuster 23, which correspond to the respective outputs of the oscillator cycle accumulator 10 and the TDC system 20, are then combined through the summer block 60 for outputting the measured DCO phase.

The wanted DCO phase is created in the phase accumulator 30. At each reference clock cycle, the phase accumulator 30 outputs an updated phase value resulting from the sum of the previous phase value with a phase update frequency-setting word FSW, which programming digital word FSW sets the DCO output frequency FOUT in relation to the reference clock signal FREF. It is to be noted that the phase update frequency-setting word FSW should be coded across many bits to allow sufficient synthesis precision. For example, coding the phase update frequency-setting word FSW across 27 bits is required to create RF frequencies centered on 4 GHz to a precision of a few dozens of Hz. One part of this programming digital word FSW encodes complete DCO clock cycles per reference period, namely integer increments of 2π or an integer phase information, whereas the other part of this programming digital word FSW encodes fractions of a DCO clock cycle, namely a fractional phase information much less than 2π radians. For example, for a reference clock at 26 MHz, a common frequency used in systems operating to the GSM standard, the number of 4 GHz DCO clock cycles that accumulate per reference period is about 156. For a phase update frequency-setting word FSW encoded across 27 bits, the integer phase information can thus be encoded using 8 bits, thereby leaving 19 bits to encode the fractional phase information. It is to be noted that in the case of a frequency-modulated ADPLL, the phase update frequency-setting word FSW can be dynamically adjusted at each reference cycle to introduce changes in the DCO output frequency FOUT.

The difference detected by the PED 70, between the measured DCO phase issued from the summer block 60 and the wanted phase consigned by the phase accumulator 30, represents the phase error ε, which drives the ADPLL lock. These digital phase values are merely subtracted, and the resultant phase error ε is input to the loop filter 40, e.g. a low-pass filter. In its simplest form, the loop filter 40 may be a gain circuit to create a first-order feedback loop. However, a second-order filter including a zero has the advantage to ensure adequate stability of the feedback loop. The loop filter 40 then outputs the frequency control signal as a digital word, which sets the DCO output frequency FOUT and is updated at the reference frequency rate.

In order to perform a finer code-to-phase adjustment, the adjuster 23 can also be replaced by a look-up table rather than by a multiplier for undertaking the gain normalization. Indeed, the results of occurrence probabilities per TDC output code value obtained, using the storage element in the first embodiment or the set of counters in the second embodiment, and also the processor, are not only used to normalize the mean TDC unit delay and hence the TDC gain, but can also serve to correct for TDC non-linearity. This results from the fact that any TDC output code value that occurs more frequently than the average is due to a longer delay attributed to the corresponding delay element, while any TDC output code value that occurs less frequently than the average is due to a shorter than normal delay. It is therefore possible to construct a look-up table, e.g. a mapping function, that assigns, for each raw TDC output code value produced by the TDC core 21, a corresponding estimated phase error (within a range of 2π) based on the sum of these delay values in connection with all previous TDC output code values.

For example, taking the total number of measured TDC cycles as say M, if each TDC delay element were to be exactly equal, then we would expect that each code value would be observed on average M/N times, with N being the number of unit TDC delays that correspond to 2π of the DCO cycle. If during the gain normalisation a particular code value occurrence differs from this nominal value by “delta”, so that the number of occurrences of that code value in total of M cycles is equal to “M/N +delta”, then the unit delay corresponding to this instance of the TDC delay element is correspondingly greater for positive deltas, and lesser for negative deltas. The average rate of occurrence of this particular code is obtained by dividing by M, to give a probability of (1/N+delta/M). Thus whereas the nominal TDC delay, when normalised to the phase of the controllable oscillator, is given by 2π/N, when we take into account the occurrence rate of a particular code including any offset “delta”, then the delay becomes =2π (1/N+delta/M). This calculation is performed for each TDC unit delay, except for the first and last codes for which the information is not available. The TDC unit delays corresponding to the first and last code values are set equal to the mean, i.e. nominal, TDC unit delay calculated from all other used code values.

The look-up table is required to convert the TDC code value to a corresponding time delay through the TDC. This requires summing the delays through each preceding TDC element, for example, code 5 corresponds to the delay through TDC elements 1 to 5. In the look-up table, if no correction per individual TDC delay element is made then code 5 is mapped to 5× the nominal unit delay, that is 5*(2π/N). If the correction is made, then code 5 is mapped to: [5*(2π/N)]*[delta(1)+delta(2)+delta(3)+delta(4)+delta(5)]/M, where delta(1) corresponds to the difference in occurrence for TDC code 1, delta(2) to the difference in occurrence for TDC code 2, and so on.

Thus, once the set of delay values has been estimated for each raw TDC output code value, it is no longer needed to have the adjuster 23 acting as a multiplier as previously mentioned, such that it can be replaced by that look-up table for performing a finer code-to-phase adjustment. The look-up table content is then forwarded as a fractional phase term in order to be combined together with the output of the summer block 14 for outputting, through the summer block 60, the measured DCO phase.

It should be noted that the fine code-to-phase adjustment can be achieved with sufficient confidence only when a large amount of samples have been evaluated, in order to reduce the statistical estimation error. For example, an average gain normalization process based on about 25 to 30 samples per TDC output code value could be reasonably performed, and a size of the storage element of 256 words would allow a normalization for a 25 ps nominal unit delay and a 4 GHz DCO frequency. A larger sample size would ideally be required for individual TDC output code calibration, and a size of the storage element of 4096 words for example would reduce the statistic uncertainty by a factor of 4, the uncertainty in the estimated value being reduced by a rate proportional to the square root of the number of samples.

Applications contemplated for such ADPLL may be a TDC-based RF frequency synthesizer of a RF transceiver fully compliant to GSM, EDGE, UMTS, CDMA, Bluetooth, WLAN or DECT standards in advanced sub-micron CMOS technology such as 90, 65 or 45 nm nodes. Additionally, the results of occurrence probabilities per TDC output code value, obtained using the storage element or the plurality of counters and the processor, can also be used to enhance production testing. Firstly, many more code values can be read and stored in an additional storage element, e.g. a memory, on chip or in the tester, in order to reduce statistical uncertainty. Then, a test program, using the on-chip implemented hardware, e.g. a memory or an algorithm, or any external processing, can check whether there are no missing TDC output code values, whether the spread of the TDC output code values is less than some defined threshold in order to ensure overall TDC linearity requirements, and whether the normalized TDC unit delay is within expected bounds in order to meet synthesis performance specifications such as the in-band noise floor.

In summary, an ADPLL 200 having a TDC system 20 being normalized based on the analysis of the occurrence probability of raw TDC output code values and the expected flat probability distribution curve has been described. The TDC system 20 comprises a TDC core 21, a gain normalizatIon circuit 22 and an adjuster 23. The TDC core 21 comprises a set of nominally identical delay elements and converts the time difference between the edges of the reference clock signal FREF and the DCO block signal CLK into a raw TDC output code as a digital word. The gain normalization circuit 22 comprises at least either a storage element for storing the continuously updated sequence of raw TDC output code values or a plurality of counters, each of which is associated with a respective output code for counting the number of occurrences of each TDC output code value, and a processor for respectively analyzing the content of the storage element or of each counter based on an occurrence probability of the TDC output code values. The adjuster 23 can act as a multiplier or a lookup table depending on the proposed analysis. Thereby, the TDC gain normalization can be correctly assessed whatever the detected time difference.

While the invention has been illustrated and described in detail in the drawings and foregoing description, such illustration and description are to be considered illustrative and not restrictive; the invention is not limited to the disclosed embodiments.

Other variations to the disclosed embodiments can be understood and effected by those skilled in the art in practicing the claimed invention, from a study of the drawings, the disclosure, and the appended claims.

For example, the ADPLL 200 of FIG. 2 in connection with the oscillator cycle accumulator 10 of FIG. 2a may not comprise the summer block 60. In this case, the output of the TDC system 20 can be provided to the summer block 14 in order to be combined with the respective outputs of the counter 12 and the state decoder 13. Thereby, the summer block 14 can issue the measured DCO phase directly to the PED 70.

In another example related to a production test environment, the ADPLL 200 of FIG. 2 may be implemented within an integrated circuit (IC) in such a manner that the gain correction circuit 24, which is formed of the gain normalization circuit 22 and the adjuster 23 of FIG. 2b, is not located inside the ADPLL 200, i.e. on-chip, but outside the ADPLL 200, i.e. off-chip. In this case, the ADPLL 200 under test will comprise a storage element, e.g. a one-time programmable (OTP) memory, which will be programmed by the result obtained from the production test once the ADPLL 200 has been tested. Such result may then consist of either the correction coefficient, i.e. the mean gain correction coefficient, determined by the processor and used by the multiplier for adjusting the TDC gain normalization, or the complete content of the look-up table corresponding to fine tuning variations in each TDC time step.

Provided that the TDC gain normalization can be performed on-chip or off-chip at different moments, a further example related to the implementation of a plurality of ADPLLs 200 within the same IC can show that the gain correction circuit 24, which is formed of the gain normalization circuit 22 and the adjuster 23 of FIG. 2b, may also be shared between these multiple ADPLLs 200 for reducing cost.

Although the TDC system of the invention has been described herein in the context of an ADPLL having a digitally controlled oscillator (DCO), it will be understood that the TDC system is equally applicable to oscillators controlled by other means, such as a voltage controlled oscillator (VCO).

In the claims, the word “comprising” does not exclude other elements or steps, and the indefinite article “a” or “an” does not exclude a plurality. A single or other unit may fulfill the functions of several items recited in the claims. The mere fact that certain measures are recited in mutually different dependent claims does not indicate that a combination of these measured cannot be used to advantage.

A computer program may be stored/distributed on a suitable medium, such as an optical storage medium or a solid-state medium supplied together with or as part of other hardware, but may also be distributed in other forms, such as via the Internet or other wired or wireless telecommunication systems.

Finally, any reference signs in the claims should not be construed as limiting the scope of the claims.

1. A time-to-digital converter (TDC) system which can be used in an all-digital phase-locked loop circuit, said TDC system comprising:
a TDC core configured to receive a controllable clock signal from a controllable oscillator and a reference clock signal from a reference oscillator, and to convert a time difference between edges of said controllable clock signal and said reference clock signal into an output code; and
a gain correction circuit for correcting a gain of said TDC core, said gain correction circuit comprising:
a gain normalization circuit configured to normalize the gain of said TDC core to a period of said controllable oscillator; and
an adjuster in connection with said gain normalization circuit, said adjuster configured to carry out the gain normalisation by adjusting said output code; wherein,
said TDC core comprises a set of nominally identical delay elements, each delay element introducing a unit delay; and
said gain normalization circuit comprises a processor configured to analyze an occurrence probability of said output codes, and to determine an adjustment to be made by the adjuster according to said occurrence probability.

2. The TDC system according to claim 1, wherein said gain normalisation circuit further comprises a storage element configured to store a plurality of said output codes for the processor.

3. The TDC system according to claim 1, wherein said gain normalisation circuit further comprises a plurality of counters, each of which is associated with a respective output code, configured to count a number of occurrences of each value of said output codes for the processor.

4. The TDC system according to claim 1, wherein said adjuster is a multiplier, said multiplier being configured to multiply said output code by a correction coefficient that is determined by the processor.

5. The TDC system according to claim 1, wherein said adjuster is a look-up table, said look-up table being configured by the processor to assign a corresponding phase error estimate to each of said output code.

6. The TDC system according to claim 1, wherein said processor estimates a number N of said unit delays per controllable oscillator cycle according to a relation:
$$\begin{matrix}N = \{ ( {codevalue}_{last but one} ) + \frac{{occurrence}_{last code}}{{averageoccurrences}_{all other codes}} \} \\ = \frac{controllable oscillator period}{unit delay}\end{matrix}$$
where said code value_{last but one} is a value of a last but one output code.

7. The TDC system according to claim 1, wherein said controllable clock signal is provided to said TDC core through a delay element, and wherein said processor estimates a number N′ of said unit delays per controllable oscillator cycle according to a relation:
$$\begin{matrix}{N}^{′} = \{ \begin{matrix}( {codevalue}_{last but one} - {codevalue}_{second} ) + \\ \frac{{occurrence}_{last code} + {occurrence}_{first code}}{{averageoccurrences}_{all other codes}}\end{matrix} \} \\ = \frac{controllable oscillator period}{unit delay} ,\end{matrix}$$
where said code value_{last but one} is a value of a last but one output code, and said code value_{second} is a value of a second output code.

8. The TDC system according to claim 1, wherein the controllable oscillator is a digitally controlled oscillator.

9. An integrated circuit comprising an all-digital phase-locked loop (ADPLL) circuit that includes the TDC system of claim 1, wherein the gain correction circuit is implemented outside of said integrated circuit, and the results provided by said gain correction circuit are stored within said integrated circuit.

10. A method of normalizing a time-to-digital converter (TDC) system, said TDC system including:
a TDC core configured to receive a controllable clock signal from a controllable oscillator and a reference clock signal from a reference oscillator, and to convert a time difference between edges of said controllable clock signal and said reference clock signal into an output code; and
a gain correction circuit for correcting a gain of said TDC core, said gain correction circuit including:
a gain normalization circuit configured to normalize the gain of said TDC core to a period of said controllable oscillator; and
an adjuster in connection with said gain normalization circuit, said adjuster configured carry out the gain normalisation by adjusting said output code; wherein,
said TDC includes a set of nominally identical delay elements, each delay element introducing a unit delay; and
said gain normalization circuit includes a processor configured to analyze an occurrence probability of said output codes, and to determine an adjustment to be made by the adjuster according to said occurrence probability,
the method comprising:
determining the occurrence probability by counting the number of occurrences for each code value and comparing to a total number of code values; and
adjusting the adjuster according to said occurrence probability to normalize the gain of said TDC core to the period of said controllable oscillator.

11. The method of claim 10, wherein the determining and adjusting steps of claim 10 comprise:
counting a number of occurrences of each value of said output codes ranging between a lowest value (nₘᵢₙ) and the highest value (nₘₐₓ);
calculating an average occurrence (nₘₑₐₙ) of all values of said output codes ranging between said lowest value (nₘᵢₙ) and the highest but one value (nₘₐₓ₋₁);
calculating a ratio between the occurrence of said highest value (nₘₐₓ) and said average occurrence (nₘₑₐₙ);
mathematically estimating a number N of said unit delays per controllable oscillator cycle, wherein:
$$\begin{matrix}N = \{ ( {codevalue}_{last but one} ) + \frac{{occurrence}_{last code}}{{averageoccurrences}_{all other codes}} \} \\ = \frac{digitally controllable oscillator period}{unit delay}\end{matrix}$$
where said code value_{last but one} is a value of a last but one output code; and
adjusting the adjuster to normalise the gain of said TDC core to the period of said controllable oscillator.

12. The method of claim 10, wherein said controllable clock signal is provided to said TDC core through a delay element, and wherein the determining and adjusting steps of claim 10 comprise:
counting a number of occurrences of each value of said output codes ranging between a lowest value (nₘᵢₙ) and a highest value (nₘₐₓ);
calculating an average occurrence (nₘₑₐₙ) of all values of said output codes ranging between a lowest plus one value (nₘᵢₙ₊₁) and a highest but one value (nₘₐₓ₋₁);
calculating a ratio between the occurrence of said lowest value (nₘᵢₙ) and said average occurrence (nₘₑₐₙ);
calculating a ratio between the occurrence of said highest value (nₘₐₓ) and said average occurrence (nₘₑₐₙ);
mathematically estimating said number N′ of said unit delays per controllable oscillator cycle, wherein:
$$\begin{matrix}{N}^{′} = \{ \begin{matrix}( {codevalue}_{last but one} - {codevalue}_{second} ) + \\ \frac{{occurrence}_{last code} + {occurrence}_{first code}}{{averageoccurrences}_{all other codes}}\end{matrix} \} \\ = \frac{digitallycontrollableoscillator period}{unit delay} ,\end{matrix}$$
where said code value_{last but one} is a value of a last but one output code, and said code value_{second} is a value of the second output code; and
adjusting the adjuster to normalise the gain of said TDC core to the period of said controllable oscillator.

13. The method of claim 11, wherein said gain normalisation circuit further includes a storage element configured to store a plurality of said output codes for the processor, and wherein the method further comprises:
storing the values of said output codes in said storage element;
bubble-sorting the stored values;
detecting the highest value (nₘₐₓ) of said output codes; and
detecting the lowest value (nₘᵢₙ) of said output codes.

14. The method of claim 11, wherein said gain normalisation circuit further includes a plurality of counters, each of which is associated with a respective output code, configured to count the number of occurrences of each value of said output codes for the processor, and wherein the method further comprises:
detecting the highest value (nₘₐₓ) of said output codes;
detecting the lowest value (nₘᵢₙ) of said output codes;
retrieving from each of said plurality of counters the number of occurrences of each value of said output codes ranging between said lowest value (nₘᵢₙ) and said highest value (nₘₐₓ).

15. The method of claim 10, further comprising storing the results provided by the gain correction circuit in a storage element of an all digital phase locked loop, the all digital phase locked loop further including the TDC system.

16. The method of claim 10, further comprising controlling the TDC system to determine acceptance and rejection of said TDC system according to a predetermined number of occurrences of each value of said output codes.
